(19) United States
(12) Patent Application Publication
(10) Pub. No.: US 2020/0227618 A1
(43) Pub. Date: Jul. 16, 2020

(54) PROTECTIVE BARRIER LAYERS FOR SUPERCONDUCTING STRUCTURES

(71) Applicant: Auburn University, Auburn, AL (US)

(72) Inventors: Michael C. HAMILTON, Auburn, AL (US); Vaibhav GUPTA, Auburn, AL (US); Mark Lee ADAMS, Auburn, AL (US)

(21) Appl. No.: 16/247,234

(22) Filed: Jan. 14, 2019

(51) Int. Cl. H01L 39/24; H01L 39/02

(52) U.S. Cl. CPC H01L 39/2406; H01L 39/02

(57) ABSTRACT

One or more dielectric barriers, such as, but not limited to, aluminum oxide (Al2O3), is used to isolate and protect super conductive (SC) structures. The SC structures are formed from SC materials, such as, but not limited to, niobium, from other surrounding materials. Using the barriers significantly reduces and/or eliminates the degradation of the superconducting properties of the SC structures during subsequent fabrication steps that employ elevated temperatures. As a result, incorporation of the barriers relaxes the need to use lower temperature fabrication processes and opens up possibilities for use of different more desirable processes and/or materials during subsequent fabrication steps.

### FIELD OF THE DISCLOSURE

The present disclosure relates to superconductors, and in particular to providing one or more barrier layers to protect superconducting structures.

### BACKGROUND

Thin film niobium (Nb) is widely used as a superconducting material in superconducting (SC) electronics, such as SC integrated devices, circuits, and the like. The superconducting properties of niobium may be significantly degraded and often completely destroyed when the niobium is subjected to fabrication processes that involve temperatures at or above approximately 250° C. Other SC materials suffer the same fate at elevated fabrication temperatures. Accordingly, foundries that process niobium-based SC integrated circuits go to significant effort to design fabrication processes that do not exceed potentially damaging temperatures in order to maintain the superconducting properties of the niobium or like SC material. Furthermore, in many designs, the niobium is deposited in a layer, which is patterned to form SC structures. These SC structures are sandwiched between two dielectric layers. A common and desirable material for the dielectric layers is polyimide. Curing polyimide above a certain temperature is believed to lead to the diffusion of oxygen, hydrogen, or other degrading materials into the SC material, thereby greatly diminishing and/or destroying the SC properties of the niobium.

### SUMMARY

One or more dielectric barrier layers, such as, but not limited to, aluminum oxide (Al₂O₃), is used to isolate and protect super conductive (SC) structures. The SC structures are formed from SC materials, such as, but not limited to, niobium, from other surrounding materials. Using the barrier layers prevents the loss or degradation of the superconducting properties of the SC structures during subsequent fabrication steps that employ elevated temperatures. As a result, incorporation of the barrier layers relaxes the need to use lower temperature fabrication processes and opens up possibilities for use of different and more desirable processes and/or materials during subsequent fabrication steps.

An exemplary method includes the following steps. Initially, a substrate is provided. Optionally, a lower barrier is provided over the substrate. The lower barrier is formed from a first dielectric material. At least one superconductive structure is formed over the substrate, and if provided, the lower barrier. The at least one superconductive structure is formed from a superconductive material that provides superconductivity within at least a portion of the at least one superconductive structure. An upper barrier is provided over the at least one superconductive structure and portions of the substrate, or if provided, the lower barrier. The lower and upper barriers may be formed from the same or different dielectric materials. A dielectric layer is provided over the upper barrier. The dielectric layer is formed from a potentially destructive dielectric material, which is different from the materials used for the lower and upper barriers. The lower and upper barriers separate the at least one superconductive structure from the dielectric layer. Next, the potentially destructive dielectric layer is heated above a destructive temperature that would normally result in loss or degradation of superconductivity of the at least one superconductive structure without the presence of the lower and/or upper barriers.

In one embodiment, the superconductive material is at least one of a group consisting of niobium (Nb), aluminum (Al), titanium (Ti), tin (Sn), lead (Pb), indium (In), chromium (Cr), palladium (Pd), tantalum (Ta), and a compound containing at least one of niobium (Nb), aluminum (Al), titanium (Ti), tin (Sn), lead (Pb), indium (In), chromium (Cr), palladium (Pd), and tantalum (Ta). In one embodiment, the first material is at least one of a group consisting of aluminum oxide (Al2O3), titanium dioxide (TiO2), and hafnium oxide (HfO).

In another embodiment, a superconducting apparatus comprises a substrate, a lower barrier, at least one superconducting structure, an upper barrier, and a dielectric layer. The lower barrier resides over the substrate and is formed from a first material. The at least one superconductive structure resides over the lower barrier and is formed from a superconductive material that provides superconductivity within at least a portion of the at least one superconductive structure. The upper barrier resides over the at least one superconductive structure and portions of the lower barrier. The upper barrier is formed from the first material, and the lower barrier and the upper barrier encapsulate the at least one superconductive structure. The dielectric layer resides over the upper barrier and is formed from a potentially destructive dielectric material, which is different from the first material. The destructive nature of the dielectric material is triggered when it is heated to relatively high temperatures during fabrication.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a wafer with SC structures according to the related art.

FIG. 2 illustrates a wafer with SC structures according to a first embodiment of the disclosure.

FIG. 3 illustrates a wafer with SC structures according to a second embodiment of the disclosure.

FIG. 4 illustrates a wafer with SC structures according to a third embodiment of the disclosure.

FIG. 5 illustrates a wafer with SC structures according to a fourth embodiment of the disclosure.

FIG. 6 is a graph of normalized resistance versus temperature when a polyimide dielectric is cured at 225° C. and 375° C. without the use of barrier layers to protect the SC structures.

FIG. 7 is a graph of normalized resistance versus temperature when a polyimide dielectric is cured at 225° C. and 375° C. with the use of barrier layers to protect the SC structures.

FIGS. 8 through 14 illustrate an exemplary process for fabricating the wafer illustrated in FIG. 3.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In this disclosure, one or more thin-film dielectric barrier layers, such as, but not limited to, aluminum oxide (Al₂O₃), are used to isolate and protect superconductive (SC) structures. The SC structures are formed from SC materials, such as but not limited to niobium, from other surrounding materials. Using the barrier layers prevents the loss or degradation of the superconducting properties of the SC structures during subsequent fabrication steps that employ elevated temperatures. As a result, incorporation of the barrier layers relaxes the need to use lower temperature fabrication processes and opens up possibilities for use of different more desirable processes and/or materials during subsequent fabrication steps. Prior to delving into the details of these concepts, an overview of a traditional wafer that includes SC structures is described.

With reference to FIG. 1, an exemplary portion of a traditional wafer 10 is illustrated. The wafer includes a substrate 12 and any number of superconductive (SC) structures 14, such as the traces, pads, planes, and the like, as well as any number of passive or active components, such as diodes, transistors, and the like (not shown). The SC structures 14, passive devices, and active devices may be integrated in or on the wafer 10. The SC structures 14 are formed from materials that have superconductive properties within certain temperature ranges. A widely used superconductive material is niobium (Nb), which is generally applied as a thin film that is etched to form the SC structures 14.

A dielectric, such as a polyimide dielectric 16, is provided over the exposed portions of the substrate as well as the SC structures 14. Most polyimide dielectrics 16 should be cured at temperatures at or above 300 to 350° C. for proper and thorough curing; however, to prevent damage to SC structures 14, which are formed from niobium or the like, the curing temperatures are often capped at 250° C. to prevent the SC structures 14 from losing their superconductive properties. Limiting the curing temperatures limits the effectiveness of the curing process for the polyimide dielectric 16, and as such, limits the functional effectiveness of polyimide dielectric 16. Again, while niobium-based SC structures 14 and polyimide dielectrics 16 are discussed in detail, other SC and dielectric materials suffer in the same or similar fashion. The concepts described below allow these same materials to be used in higher temperature fabrication processes without damaging the SC properties of the SC materials that are used for the SC structures 14.

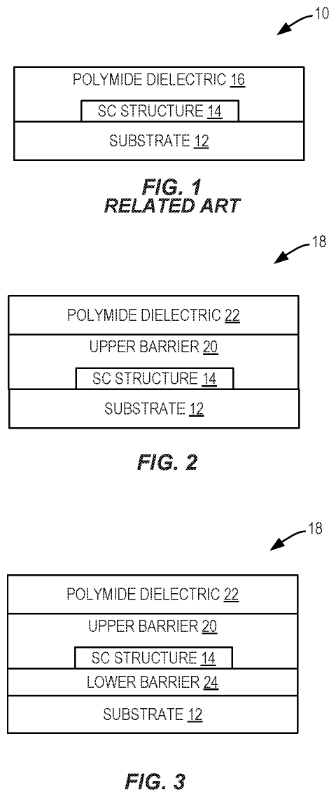

FIG. 2 illustrates a unique structure for a wafer 18 according to a first embodiment. For the present disclosure, the SC structures 14 are insulated from the polyimide dielectric 22, or other dielectric that has potentially destructive characteristics, using an appropriate barrier. The superconductive structures 14 are formed over a top surface of the substrate 12, and an upper barrier 20 is formed over the top and around the sides of the SC structures 14. A polyimide dielectric 22, or the like, is provided over the upper barrier 20, wherein the upper barrier 20 separates the polyimide dielectric 22 from the SC structures 14. If the SC structures 14 are formed from niobium, a particularly beneficial material to use for the upper barrier 20 is aluminum oxide (Al₂O₃).

Exemplary, but non-limiting, superconductive materials that may be used for the SC structures 14 include niobium (Nb), aluminum (Al), titanium (Ti), tin (Sn), lead (Pb), indium (In), chromium (Cr), palladium (Pd), and tantalum (Ta), as well as compounds containing one or more of the same, such as, Nb₃Ge, Nb₃Si, NbN, and the like. Other exemplary, but non-limiting compounds may include MgB₂, NbTi, NbTiN, Nb₃Al, Nb₃Sn, Nb₃Ga, and the like. Exemplary, but non-limiting, materials for the upper barrier layer 20 include aluminum oxide (Al₂O₃) titanium dioxide (TiO₂), hafnium oxide (HfO), and the like. Exemplary combinations of materials for the SC structures 14 and the upper barrier layer 20 include niobium and aluminum oxide; niobium and titanium dioxide, and the like. Exemplary materials for the substrate 12 include, but are not limited to silicon (Si), silica (glass), sapphire, fused silica, polyimide (kapton), and the like. While the exemplary dielectric material used for discussion is polyimide, other dielectric materials that may affect the SC structures at higher processing temperatures include, but are not limited to silicon dioxide, silicon nitride, ALX 2010, ALX 2030, benzocyclobutene (BCB), and the like.

The polyimide material used for the polyimide dielectric 22 in the disclosed examples is Dupont's HD-4110 from HD Microsystems. The polyimide dielectric 22 is not limited to HD-4110, as those skilled in the art will appreciate. One goal is to be able to effectivity use those dielectric (and other) materials that require high temperature processing and would normally affect the superconductivity of the SC structures 14 when processed at these high temperatures without the use of the concepts provided herein. While only one SC structure 14 is illustrated in the various embodiments, those skilled in the art will recognize that the wafer 18 and any die, conductors, cabling, or the like formed therefrom will likely include a plurality of such elements that may take on any number of shapes and sizes.

Turning now to FIG. 3, a second embodiment of the disclosure is illustrated. In this embodiment, the wafer 18 includes both a lower barrier 24 and an upper barrier 20, which effectively sandwich or otherwise surround the SC structures 14. The lower barrier 24 and the upper barrier 20 may be formed from the same or different dielectric materials. In one embodiment, the lower barrier 24 and the upper barrier 20 are formed from aluminum oxide, and the SC structure 14 is formed from niobium or a compound formed therefrom. All of the materials listed above for the upper barrier 20 may be used for the lower barrier 24.

The concepts described herein employ one or more barrier layers, such as the lower and upper barrier layers 24, 20, to protect the superconductive characteristics of the SC structures 14 during high temperature fabrication steps. Superconductivity for a superconductive material is defined herein as having a resistivity of zero below the transition of the superconductive material. An SC structure 14 is defined as an structure that is formed from a SC material and provides superconductivity throughout all or a portion of the structure. Using the concepts described herein, the superconductivity of the SC materials for the SC structures 14 is not lost, but may be marginally effected, even when the SC structures 14 are subjected to subsequent fabrication process temperatures at or above 250° C., 275° C., 300° C., 350° C., and even 375° C.

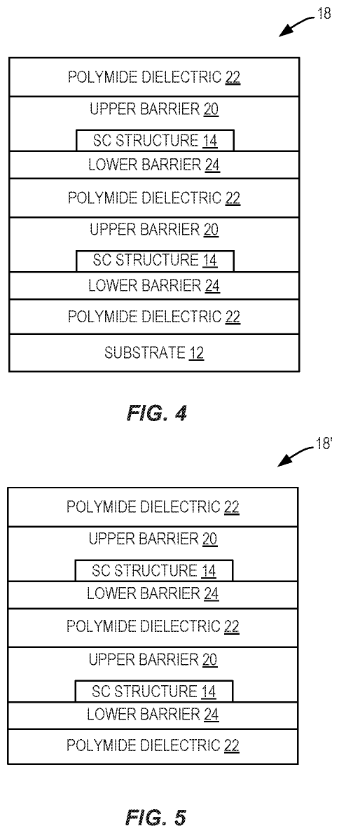

As illustrated in FIG. 4, the wafer 18 may have any number of conductive layers, wherein SC structures 14 are effectively stacked above one another at different levels. As illustrated, a first polyimide dielectric 22 is formed over the substrate 12, and a first lower barrier 24 is formed over the first polyimide dielectric 22. SC structures 14 are formed at a first level, and over the lower barrier 24. A first upper barrier 20 is formed over and around the SC structures 14, and a second polyimide dielectric 22 is formed over the first upper barrier 20. A second lower barrier 24 may be formed over the polyimide dielectric 22, and a second level of SC structures 14 may be formed over the second lower barrier 24. The second upper barrier 20 may be formed over and around the second level of SC structures 14, and a third polyimide dielectric 22 may be formed over the upper barrier 20. While only two superconductive levels are illustrated in FIG. 4, those skilled in the art will appreciate that any number of superconductive levels may be provided in the wafer 18. Further, any vertical elements, such as vias and the like, may be surrounded by an appropriate barrier material to effectively isolate the SC structures 14 from potentially damaging dielectric elements.

FIG. 5 illustrates yet another embodiment wherein the substrate 12 is removed from the embodiment illustrated in FIG. 4. Removing the substrate 12 allows the structure to flex more effectively and allows it to be used as a base for a superconductive cable or the like.

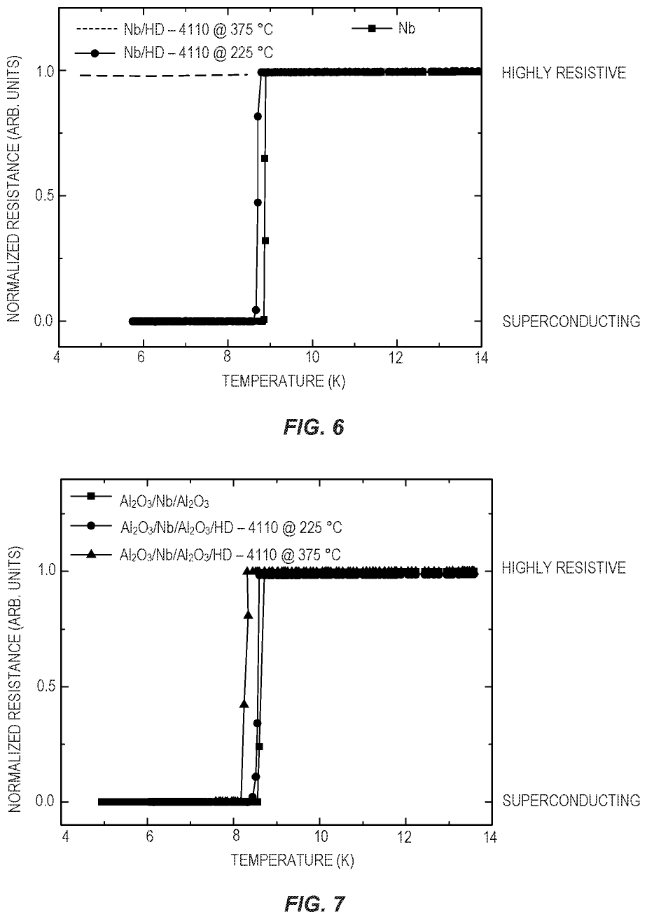

FIGS. 6 and 7 illustrate the effectiveness of using aluminum oxide for the lower and upper barriers 24, 20 to protect thin and narrow, niobium-based SC structures 14 during fabrication processes that cure polyimide-based dielectrics 22 at elevated temperatures. FIG. 6 plots normalized resistance versus temperature in Kelvin (K) for three scenarios that do not use the lower and upper barriers 24, 20. The first scenario (Nb-square line) is one in which there is no polyimide dielectric 22 and no processing at elevated temperatures. The transition from a normal state (highly resistive) to a superconducting state of the niobium-based SC structures 14, as temperature was reduced, exhibits a fairly abrupt transition, as the desirable and expected, at about 9 K.

The second scenario (Nb/HD-4110 @ 225° C.-circle line) is one in which the polyimide dielectric 22 was provided; however, the polyimide dielectric 22 was cured at a reduced temperature of 225° C. in a nitrogen (N₂) atmosphere. With the reduced curing temperature, only a small amount of degradation occurs, which corresponds to a small reduction in the critical transition temperature T_{c}. In other words, the transition from the normal state (highly resistive) to the superconductive state is shifted only slightly to the left (i.e. lower in temperature). Further, only a minimal degradation in the critical current I_{c} and residual resistance ratio (RRR) measurements (not shown) occurs. The critical current I_{c} drops from 186 mA to 182 mA, and the RRR drops from 3.58 to 3.34.

The third scenario (Nb/HD-4110 @ 375° C.-dashed line) is one in which the polyimide dielectric 22 was provided and cured at an elevated temperature of 375° C. in a nitrogen (N₂) atmosphere. In this scenario, superconductivity of the SC structures 14 was destroyed, as the SC structures 14 remained highly resistive at temperatures below 9K.

FIG. 7 plots normalized resistance versus temperature in Kelvin (K) for three scenarios, which use the lower and upper barriers 24, 20 to encapsulate the SC structures 14. The first scenario (Al₂O₃/Nb/Al₂O₃-square line) is one in which there is no polyimide dielectric 22 and no processing at elevated temperatures. The transition from a normal state (highly resistive) to a superconducting state of the niobium-based SC structures 14, as temperature was reduced, exhibits a fairly abrupt transition, as the desirable, just below 9 K.

The second scenario (Al₂O₃/Nb/Al₂O₃/HD-4110 @ 225° C.-circle line) is one in which the polyimide dielectric 22 was provided; however, the polyimide dielectric 22 was cured at a reduced temperature of 225° C. in a nitrogen (N₂) atmosphere. With the reduced curing temperature, only a small amount of degradation occurs, which corresponds to a small reduction in the critical transition temperature T_{c}. In other words, the transition from the normal state (highly resistive) to the superconductive state is shifted only slightly to the left (i.e. lower in temperature). Further, only a minimal degradation in the critical current I_{c} and residual resistance ratio (RRR) measurements (not shown) occurs. The critical current I_{c} drops from 186 mA to 182 mA, and the RRR drops from 3.58 to 3.34. These findings show that the use of the lower and upper barriers 24, 20 have an insignificant impact at reduced processing temperatures.

The third scenario (Al₂O₃/Nb/Al₂O₃/HD-4110 @ 375° C.-triangle line) is one in which the polyimide dielectric 22 was provided and cured at an elevated temperature of 375° C. in a nitrogen (N₂) atmosphere. Notably, superconductivity of the SC structures 14 was maintained, which is in stark contrast with the scenarios above that did not employ the lower and upper barriers 24, 20 to protect the SC structures 14. In fact, only a small amount of degradation occurs, which corresponds to a small reduction in the critical transition temperature T_{c}. In other words, the transition from the normal state (highly resistive) to the superconductive state is shifted only slightly to the left (i.e. lower in temperature) and remained above 8 K.

The critical current I_{c} and the RRR for the first scenario of FIG. 7 (no polyimide dielectric 22) were 250 mA and 3.55, respectively. For the second scenario, where the polyimide dielectric 22 was cured at 225° C., the critical current I_{c} drops to 182 mA, and the RRR drops to 3.52. For the third scenario, where the polyimide dielectric 22 was cured at 375° C., the critical current I_{c} drops to 75 mA and RRR drops to 3.22. Though there was a slight reduction in the critical transition temperature T_{c} and the RRR, and a moderate degradation in the critical current I_{c} when cured at 375° C., the niobium-based SC structures 14 retained their superconductivity and were protected by the Al₂O₃-based upper and lower barriers 24, 20.

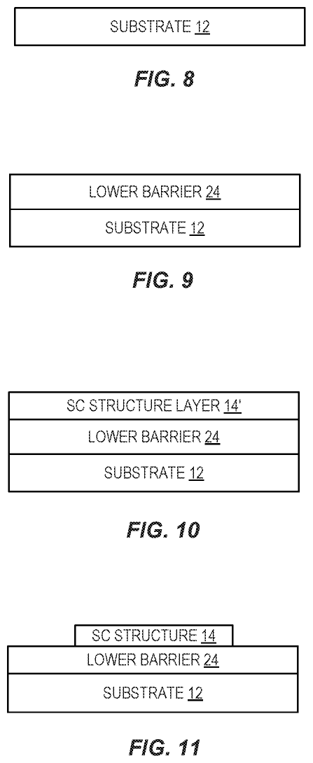

With reference to FIGS. 8-14, an exemplary process for fabricating a wafer 18 according to the above embodiments is described. Those skilled in the art will recognize that there are other ways to fabricate the wafer 18, and the following process is merely one example. Initially, a substrate 12 of silicon or like material is provided, as illustrated in FIG. 8. Next, as illustrated in FIG. 9, a lower barrier 24 is deposited using atomic layer deposition (ALD) or the like. Other materials for the lower barrier 24 may be used as described above. In one particular embodiment, the lower barrier 24 is formed from aluminum oxide. Next, as illustrated in FIG. 10, a superconductive structure layer 14′, which is formed from a superconductive material such as niobium, is provided over the lower barrier 24. Other exemplary superconductive materials may be used as described above.

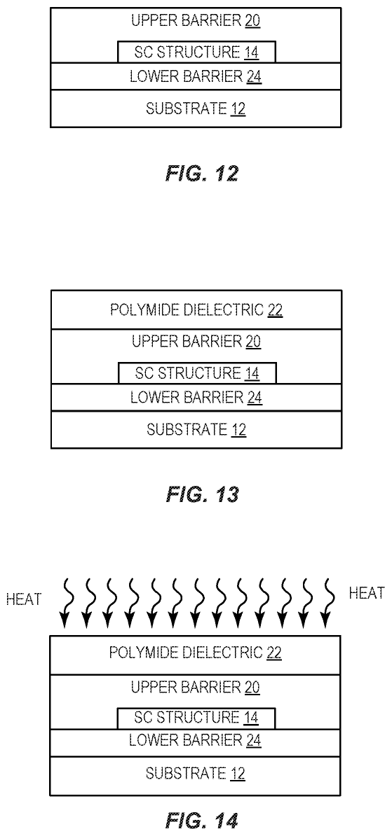

As illustrated in FIG. 11, portions of the superconductive structure layer 14′ are removed to form the SC structures 14 using appropriate etching or like removal techniques. After the SC structures 14 are formed, the upper barrier 20 is deposited over the exposed areas of the lower barrier 24, as well as over the SC structures 14, as illustrated in FIG. 12. As noted above, the upper barrier 20 may be formed from the same or different materials as the lower barrier 24. Regardless of the combination, the materials for the upper barrier 20 and the lower barrier 24 will effectively surround and/or encase the SC structures 14 in order to protect them from application of subsequent layers.

Next, a dielectric, such as a polyimide dielectric 22, is provided over the upper barrier 20, using an appropriate application or deposition process. For the polyimide dielectric 22, a polyimide paste or gel is applied over the upper barrier 20 and then heated, as illustrated in FIG. 14. Heating the polyimide dielectric 22 effectively cures the polyimide material. Notably, curing such a material often requires heating the wafer 18 to temperatures well in excess of 300° C. In many instances, proper curing requires curing temperatures at or above 350-375° C. Without the lower barrier 24 and/or upper barrier 20, which isolate the SC structures 14 from the polyimide dielectric 22, the curing process would lead to the diffusion of oxygen, hydrogen, or other degrading materials into the SC structures 14. Such diffusion would significantly reduce or destroy the superconductive properties (i.e. superconductivity) of the SC structures 14.

However, with the lower and/or upper barriers 24, 20, such diffusion is prevented and the SC structures 14 may be subjected to elevated temperatures and maintain their superconductive properties. Notably, the superconductivity of niobium and like materials are not affected, even when the polyimide dielectric 22 is cured at temperatures at or above 250° C., 275° C., 300° C., and 350° C. The concepts herein allow for heating the potentially destructive dielectric polyimide 22 or like layer above a destructive temperature that would otherwise result in the loss or degradation of superconductivity, without the presence of the lower and/or upper barriers 24, 20.

The process above may be repeated to form a second tier of like layers, as shown in FIG. 4, wherein a second lower barrier 24 is formed over the polyimide dielectric 22. A second level of SC structures 14 is formed over the second lower barrier 24, a second upper barrier 20 is formed over the SC structures 14 and portions of the second lower barrier 24, and a second polyimide dielectric 22 is formed over the second upper barrier 20. Additional tiers may be provided above the second tier.

Notably, there may be intervening layers that are not shown as well as additional layers provided over the layers shown in the above embodiments. Various SC structures 14 as well as non-SC structures may be provided in, on, or between any of the illustrated or non-illustrated layers of the wafer 18, as those skilled in the art will appreciate. Any one or more of the layers of the wafer 18 may be removed during fabrication. For example, the substrate 12 may be removed after forming the desired layers over the substrate 12.

Those skilled in the art will recognize improvements and modifications to the preferred embodiments of the present disclosure. All such improvements and modifications are considered within the scope of the concepts disclosed herein and the claims that follow.

1. A method comprising:
providing a substrate;
forming at least one superconductive structure over the substrate, wherein the at least one superconductive structure is formed from a superconductive material that provides superconductivity within at least a portion of the at least one superconductive structure;
forming a first barrier of a first material over the at least one superconductive structure, wherein the first material is an oxide;
forming a dielectric layer over the first barrier, wherein the dielectric layer is formed from a potentially destructive dielectric material, which is different from the first material, and the first barrier separates the at least one superconductive structure from the dielectric layer; and
heating the potentially destructive dielectric material above a destructive temperature that would result in loss or degradation of the superconductivity within at least a portion of the at least one superconductive structure without the presence of the first barrier.

2. The method of claim 1 further comprising forming a second barrier over the substrate prior to forming the at least one superconductive structure, wherein the second barrier is an oxide and resides between the substrate and the at least one superconductive structure, and wherein the first barrier and the second barrier are dielectric materials that encapsulate the at least one superconductive structure.

3. The method of claim 2 wherein the superconductive material comprises niobium.

4. The method of claim 2 wherein the potentially destructive dielectric material is a polyimide.

5. The method of claim 2 wherein the first material is aluminum oxide.

6. The method of claim 2 wherein the superconductive material comprises niobium, the potentially destructive dielectric material is a polyimide, and the first barrier is aluminum oxide.

7. The method of claim 1 wherein the superconductive material is at least one of a group consisting of niobium (Nb), aluminum (Al), titanium (Ti), tin (Sn), lead (Pb), indium (In), chromium (Cr), palladium (Pd), tantalum (Ta), and a compound containing of at least one of niobium (Nb), aluminum (Al), titanium (Ti), tin (Sn), lead (Pb), indium (In), chromium (Cr), palladium (Pd), and tantalum (Ta).

8. The method of claim 1 wherein the first material is at least one of a group consisting of aluminum oxide (Al₂O₃), titanium dioxide (TiO₂), and hafnium oxide (HfO).

9. The method of claim 1 wherein the superconductive material comprises niobium, the potentially destructive dielectric material is a polyimide, and the first barrier is aluminum oxide.

10. The method of claim 1 further comprising removing the substrate.

11. The method of claim 1 wherein the superconductive material comprises niobium.

12. The method of claim 1 wherein the potentially destructive dielectric material is a polyimide.

13. The method of claim 1 wherein the first material is aluminum oxide.

14. The method of claim 1 wherein the potentially destructive dielectric material is a polyimide and the first barrier is aluminum oxide.

15. The method of claim 1 wherein the destructive temperature is 300° C.

16. (canceled)

17. A superconducting apparatus comprising:
a substrate;
a lower barrier over the substrate and formed from a first material;
at least one superconductive structure over the lower barrier, wherein the at least one superconductive structure is formed from a superconductive material that provides superconductivity within at least a portion of the at least one superconductive structure;
an upper barrier over the at least one superconductive structure and portions of the lower barrier, the upper barrier formed from the first material, wherein the lower barrier and the upper barrier encapsulate the at least one superconductive structure; and
a dielectric layer over the first barrier and formed from a potentially destructive dielectric material, which is different from the first material.

18. The superconducting apparatus of claim 17 wherein the superconductive material is at least one of a group consisting of niobium (Nb), aluminum (Al), titanium (Ti), tin (Sn), lead (Pb), indium (In), chromium (Cr), palladium (Pd), tantalum (Ta), and a compound containing of at least one of niobium (Nb), aluminum (Al), titanium (Ti), tin (Sn), lead (Pb), indium (In), chromium (Cr), palladium (Pd), and tantalum (Ta).

19. The superconducting apparatus of claim 17 wherein the first material is at least one of a group consisting of aluminum oxide (Al₂O₃), titanium dioxide (TiO₂), and hafnium oxide (HfO).

20. The superconducting apparatus of claim 17 wherein the superconductive material comprises niobium; the potentially destructive dielectric material is a polyimide; and the first material is aluminum oxide.
